(19) United States
(12) Patent Application Publication
(10) Pub. No.: US 2024/0178348 A1
(43) Pub. Date: May 30, 2024

(54) LIGHT-EMITTING DEVICE AND LIGHT-EMITTING APPARATUS

(71) Applicant: TIANJIN SANAN OPTOELECTRONICS CO., LTD., Tianjin (CN)

(72) Inventors: Weihuan LI, Tianjin (CN); JInghua CHEN, Hongtang Town (CN); Peng GAO, Xiamen (CN); Fuyang NING, Tianjin (CN); Xiaofeng LIU, Xiamen (CN); Yu-Ren PENG, Tianjin (CN); Huanshao KUO, Tianjin (TW); Duxiang WANG, Tianjin (CN); Chia-Hung CHANG, Xiamen (TW)

(21) Appl. No.: 18/488,535

(22) Filed: Oct. 17, 2023

(30) Foreign Application Priority Data
Oct. 27, 2022 (CN) 202211328340.8

(51) Int. Cl. H01L 33/40; H01L 33/30

(52) U.S. Cl. CPC H01L 33/40; H01L 33/30

(57) ABSTRACT

A light-emitting device includes: an epitaxial structure having a first surface and a second surface opposite to the first surface, and including a first type semiconductor layered unit that includes a first type window layer and a first type ohmic contact layer disposed at one side of the first type window layer; an active layer; and a second type semiconductor layered unit. The first type window layer is disposed between the first type ohmic contact layer and the active layer. The first type ohmic contact layer contains a material represented by Alₓ₁Ga_{y1}InP, where 0≤x1≤1, 0≤y1≤1. The first type window layer contains a material represented by Alₓ₂Ga_{y2}InP, where 0<x2≤1, 0≤y2≤1. The first type ohmic contact layer has an Al content lower than an Al content of the first type window layer. A light-emitting apparatus that includes a light-emitting device according to the disclosure is also disclosed.

### CROSS-REFERENCE TO RELATED APPLICATION

This application claims priority to Chinese Invention Patent Application No. CN 202211328340.8, filed on Oct. 27, 2022, which is incorporated herein by reference in its entirety.

### FIELD

The disclosure relates to the semiconductor manufacturing field, and more particularly, to a light emitting device and a light emitting apparatus.

### BACKGROUND

A light-emitting diode (LED) is a semiconductor light-emitting device typically made of a semiconductor material such as GaN, GaAs, GaP, GaAsP, AlGalnP, etc., and has a PN junction for light-emission. LEDs offer advantages such as high light-emitting intensity, high energy efficiency, small size, long lifespan, etc., and are thus considered to be one of the most promising light sources currently.

A color of light emitted from an LED is closely related to a semiconductor material in the LED. By employing different semiconductor materials and structures, LEDs may emit different lights covering a full color range from ultraviolet to infrared. Aluminum gallium indium phosphide (AlGalnP) red light-emitting LEDs which have high luminance are common visible light LEDs undergoing extensive development in recent years. AlGalnP four-element red light-emitting LEDs have numerous advantages such as good current capacity, high luminous efficiency and high thermal tolerance, are irreplaceable in illumination, display and indicator applications, and are widely used in various fields of illumination.

Currently, a red light-emitting LED generally includes an AlGalnP four-element material. In such LED, the lower an Al content in an n-type semiconductor layer of an epitaxial structure of the LED is, the lower the potential barrier height is. Consequently, a lower forward voltage is required, but at the expense of a longer intrinsic wavelength for the LED. The longer intrinsic wavelength may exacerbate light absorption problem. In the existing art, a highly-doped GaAs layer is employed as an ohmic contact layer in an epitaxial structure of an LED. However, the LED containing the highly-doped GaAs layer still exhibits reduced luminance due to excessive light absorption as a result of the overly long intrinsic wavelength.

Therefore, insufficient luminous efficiency caused by the overly long intrinsic wavelength of the LED is one outstanding technical issue to be addressed.

### SUMMARY

Therefore, an object of the disclosure is to provide a light-emitting device and a light-emitting apparatus that can alleviate at least one of the drawbacks of the prior art.

According to the disclosure, the light-emitting device includes: an epitaxial structure having a first surface and a second surface opposite to the first surface, and including a first type semiconductor layered unit that includes a first type window layer and a first type ohmic contact layer disposed at one side of the first type window layer, an active layer and a second type semiconductor layered unit. The first type semiconductor layered unit, the active layer, the second type semiconductor layered unit are disposed in such order along a direction from the first surface to the second surface. The first type window layer is disposed between the first type ohmic contact layer and the active layer. The first type ohmic contact layer contains a material represented by Alₓ₁Ga_{y1}InP, where 0≤x1≤1, 0≤y1≤1. The first type window layer contains a material represented by Alₓ₂Ga_{y2}InP, where 0<x2≤1, 0≤y2≤1. The first type ohmic contact layer has an Al content lower than an Al content of the first type window layer.

According to the disclosure, the light-emitting apparatus includes the aforesaid light-emitting device.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic diagram illustrating an embodiment of an epitaxial structure according to the present disclosure.

FIG. 2 is a schematic diagram illustrating a first variation of the epitaxial structure of FIG. 1, in which a first type window layer includes a first sub-window layer and a second sub-window layer.

FIG. 3 is a schematic diagram illustrating a second variation of the epitaxial structure of FIG. 1, in which the first type window layer includes a first sub-window layer, a second sub-window layer, and a third sub-window layer.

FIG. 4 is a schematic diagram illustrating a variation of the epitaxial structure of FIG. 3, in which a second type semiconductor layered unit includes a second type capping layer, a transition layer and a second type window layer.

FIG. 5 is a schematic diagram illustrating a variation of the epitaxial structure shown in FIG. 2, in which the first type window layer has n number of a combination of the first sub-window layer and the second sub-window layer.

FIG. 6 is a schematic diagram illustrating a variation of the epitaxial structure shown in FIG. 3, in which the first type window layer has n number of a combination of the first sub-window layer, the second sub-window layer and the third sub-window layer.

FIG. 7 is a schematic diagram illustrating an embodiment of a flip chip light-emitting device according to the present disclosure.

FIG. 8 is a schematic diagram illustrating an embodiment of a vertical type light-emitting device according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

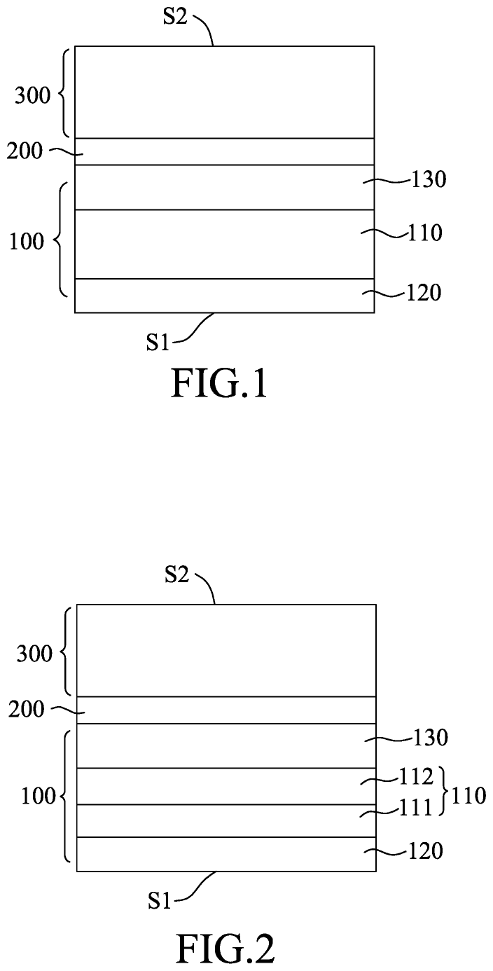

FIG. 1 is a schematic diagram illustrating an embodiment of an epitaxial structure according to the present disclosure. The epitaxial structure may be formed on a growth substrate by physical vapor deposition (PVD), chemical vapor deposition (CVD), epitaxy growth technology (EGT), or atomic layer deposition (ALD), etc. The epitaxial structure has a first surface (S1) and a second surface (S2) opposite to the first surface (S1), and includes a first type semiconductor layered unit 100, an active layer 200, and a second type semiconductor layered unit 300 that are disposed in such order along a direction from the first surface (S1) to the second surface (S2).

The first type semiconductor layered unit 100 and the second type semiconductor layered unit 300 have different conductivity types, electrical properties, and polarities, and provide holes or electrons depending on doping elements. In one embodiment, the first type semiconductor layered unit 100 is n-type, and the second type semiconductor layered unit 300 is p-type. Alternatively, the first type semiconductor layered unit 100 may be p-type, and the second type semiconductor layered unit 300 may be n-type. The active layer 200 is formed between the first type semiconductor layered unit 100 and the second type semiconductor layered unit 300. Driven by an electrical current, electrons and holes recombine within the active layer 200, and thereby converting electrical energy into light energy to emit light. The wavelength of the light radiated by the light-emitting device may be adjusted by varying the physical and chemical composition of the active layer 200.

The active layer 200 is a region in which electrons and holes recombine to radiate light. Different materials may be employed in the active layer 200 according to desired emission wavelengths. The active layer 200 may contain an aluminum gallium indium phosphide (AlGalnP)-based material and radiate red light, and may be a single heterostructure (SH), a double heterostructure (DH), a double-sided double heterostructure (DDM), or a multiple quantum well (MQW) structure. The active layer 200 includes a quantum well sub-layer(s) and a quantum barrier sub-layer(s), in which the quantum barrier sub-layer(s) has a larger band gap than the quantum well sub-layer(s). By adjusting the compositional ratio of the semiconductor materials in the active layer 200, the active layer may radiate light with different wavelengths. In certain embodiments, the active layer 200 radiates light within a wavelength range of 550 nm to 950 nm, such as red, yellow, orange, or infrared light. The active layer 200 provides electroluminescent radiation and include a material, such as aluminum gallium indium phosphide (AlGalnP) or aluminum gallium arsenide (AlGaAs). In certain embodiments, the active layer 200 includes AlGalnP and is a single quantum well structure or a multiple quantum well structure. In certain embodiments, the epitaxial structure radiates red light.

As shown in FIG. 1, the first type semiconductor layered unit 100 includes a first type window layer 110 and a first type ohmic contact layer 120 disposed on the first type window layer 110. In this embodiment, the first type window layer 110 is disposed between the first type ohmic contact layer 120 and the active layer 200. The first type ohmic contact layer 120 contains a material represented by Alₓ₁Gay InP, where 0<x1<1, 0≤y1≤1. The first type window layer 110 contains a material represented by Alₓ₂Ga_{y2}InP, where 0<x2≤1, 0≤y2≤1. The first type ohmic contact layer 120 has an Al content lower than that of the first type window layer 110.

Specifically, for a light-emitting device including the epitaxial structure which contains the AlGalnP-based material, the material represented by Alₓ₁Ga_{y1}InP (0≤x1≤1, 0≤y1≤1) is used as a material of the first type ohmic contact layer 120, the material represented by Alₓ₂Ga_{y2}InP (0<x2≤1, 0≤y2≤1) is used as a material of the first type window layer 110, and the Al content of the first type ohmic contact layer 120 is lower than the Al content of the first type window layer 110. Due to the materials of the first type ohmic contact layer 120 and the first type window layer 110, the potential barrier height between the first type ohmic contact layer 120 and the first type window layer 110 is reduced, and the intrinsic wavelengths of the first type ohmic contact layer 120 and the first type window layer 110 are reduced, thus reducing the absorption of the light radiated by the light-emitting device. In addition, the Al content of the first type ohmic contact layer 120 being lower than the Al content of the first type window layer 110 may further reduce the potential barrier height between the first type ohmic contact layer 120 and the first type window layer 110 and thus reduce the forward voltage required. The impedance of the current and the light absorption by the first type ohmic contact layer 120 and the first type window layer 110 may also be reduced, further improving the luminous efficiency of the light-emitting device.

In the present embodiment, as mentioned above, the first type ohmic contact layer 120 contains the material represented by Alₓ₁Ga_{y1}InP (0≤x1≤1, 0≤y1≤1). If X₁>0, that is, the first type ohmic contact layer 120 includes an Al-containing material which has an intrinsic wavelength smaller than an intrinsic wavelength of a conventional material, GaAs. In this case, absorption of the light radiated by the active layer 200 may be reduced, and external quantum efficiency may be enhanced. If X₁=0, that is, the first type ohmic contact layer 120 is formed from an Al-free material, i.e., GalnP, combining with the feature of the first type window layer 110 containing the material represented by Alₓ₂Ga_{y2}InP (0<x2≤1, 0≤y2≤1), the first type ohmic contact layer 120 may have an intrinsic wavelength of around 645 nm, smaller than the intrinsic wavelength of the conventional GaAs ohmic contact layer (which is around 870 nm). In this case, the light absorption may also be reduced, and the luminous intensity is enhanced, demonstrating a significant improvement over a conventional light-emitting device.

In certain embodiments, in the first type ohmic contact layer 120 containing Alₓ₁Ga_{y1}InP and the first type window layer 110 containing Alₓ₂Ga_{y2}InP, where X₂−X₁>0.2. Further, in some embodiments, X₂ may range from 0.2 to 1 and X₁ may range from 0 to 0.8. In certain embodiments, X₂ ranges from 0.5 to 1 and X₁ ranges from 0.2 to 0.5. Within these ranges, the larger the difference between X₁ and X₂ is, the larger the difference of band gaps and the larger the potential barrier will be, limiting internal electron movement. Consequently, there is an increased resistance for current flowing across layers, which may force and facilitate transverse current flow and spread, thereby enhancing the luminance and reducing the required forward voltage of an LED containing the epitaxial structure.

Further, the first type ohmic contact layer 120 has a thickness larger than 300 Å and smaller than a thickness of the first type window layer 110. In certain embodiments, the first type window layer 110 has a thickness smaller than 5 μm.

In certain embodiments, the first type ohmic contact layer 120 is n-type doped, and the first type window layer 110 is n-type doped. A doping concentration of the first type window layer 110 is lower than a doping concentration of the first type ohmic contact layer 120. The higher the doping concentration of the first type ohmic contact layer 120 is, the easier the ohmic contact with the electrode may be formed, thereby reducing the required forward voltage. The lower the doping concentration of the first type window layer 110, the lower the light absorption and the higher the luminance is. In certain embodiments, the doping concentration of the first type ohmic contact layer 120 is higher than 4E+18/cm³ and the doping concentration of the first type window layer 110 ranges from 4E+17/cm³ to 4E+18/cm³.

FIG. 2 is a schematic diagram illustrating a first variation of the embodiment of the epitaxial structure shown in FIG. 1, in which the first type window layer 110 includes a first sub-window layer 111 and a second sub-window layer 112 disposed in such order along the direction from the first surface (S1) to the second surface (S2). The first sub-window layer 111 contains aluminum indium phosphide, i.e., y2=0 in Alₓ₂Ga_{y2}InP, and the second sub-window layer 112 contains aluminum gallium indium phosphide.

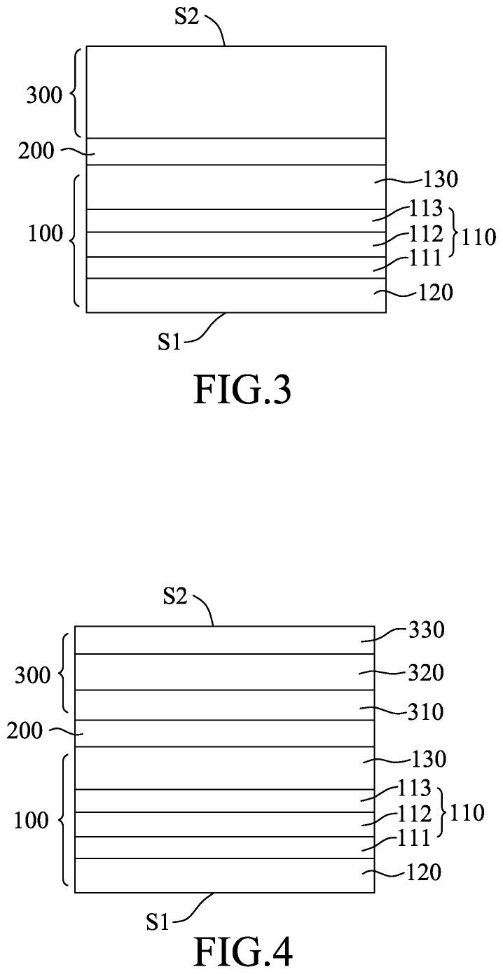

FIG. 3 is a schematic diagram illustrating a second variation of the embodiment of epitaxial structure shown in FIG. 1, in which the first type window layer 110 includes a first sub-window layer 111, a second sub-window layer 112, and a third sub-window layer 113 disposed in such order along the direction from the first surface (S1) to the second surface (S2). Further, the first sub-window layer 111 contains a material represented by AlₐGa_{b}InP, the second sub-window layer 112 contains a material represented by Al_{c}Ga_{d}InP and the third sub-window layer 113 contains a material represented by AlₑGa_{f}InP, where a>e>c, d≥0, and f>0. In the present embodiment, the first sub-window layer 111 has a thickness of TH1, the second sub-window layer 112 has a thickness of TH2 and the third sub-window layer 113 has a thickness of TH3, where 0<TH2<1000 Å<TH3<TH1. According to this design, the resulting light-emitting device has good current spreading and high luminance, and requires a low forward voltage.

In the first type window layer 110 of the epitaxial structure of FIG. 3, each of the first sub-window layer 111, the second sub-window layer 112 and the third sub-window layer 113 is n-type doped, a doping concentration of the first sub-window layer 111 is H₁, a doping concentration of the second sub-window layer 112 is H₂, and a doping concentration of the third sub-window layer 113 is H₃, where 0<H₂<H₃<H₁<4E+18/cm³.

In certain embodiments, as shown in FIG. 4, the second type semiconductor layered unit 300 may include a second type capping layer 310, a transition layer 320 and a second type window layer 330. The second type capping layer 310 is disposed between the transition layer 320 and the active layer 200, and the transition layer 320 is disposed between the second type capping layer 310 and the second type window layer 330.

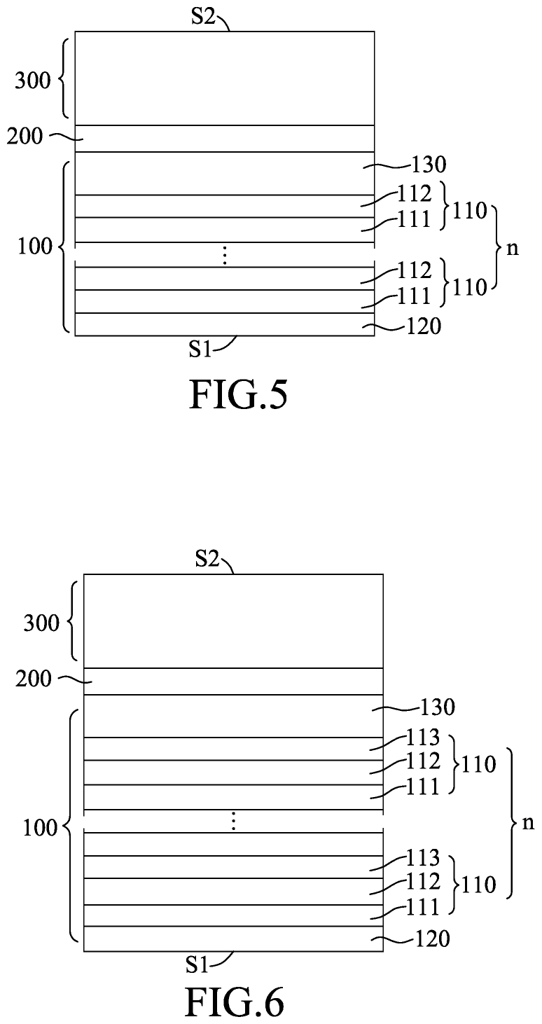

Furthermore, the first type window layer 110 may include n number of a combination of the first sub-window layer 111 and the second sub-window layer 112 in the first type window layer 110 (the first variation shown in FIG. 2), or n number of a combination of the first sub-window layer 111, the second sub-window layer 112 and the third sub-window layer 113 in the first type window layer 110 (the second variation shown in FIG. 3), where n is at least 1, e.g., 2. FIG. 5 illustrates that the first type window layer 110 in the epitaxial structure has n number of the combination of the first sub-window layer 111 and the second sub-window layer 112. FIG. 6 illustrates that the first type window layer 110 in the epitaxial structure has n number of the combination of the first sub-window layer 111, the second sub-window layer 112 and the third sub-window layer 113.

It should be noted that, in any embodiment of the epitaxial structure, any structure of the aforesaid first type semiconductor layered units may be used with any structure of the aforesaid second type semiconductor layered unit.

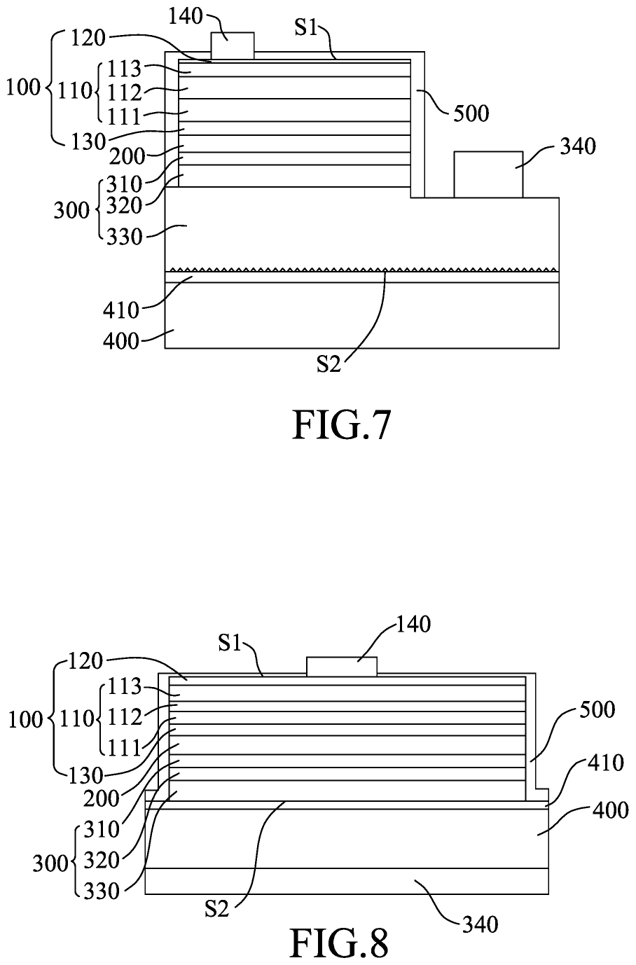

FIG. 7 is a schematic diagram illustrating an embodiment of a flip chip light-emitting device according to the present disclosure that includes any one of the aforesaid epitaxial structures and a substrate 400. As described above, the epitaxial structure has the first surface (S1) and the second surface (S2), and includes the first type semiconductor layered unit 100, the active layer 200, and the second type semiconductor layered unit 300 in such order along the direction from the first surface (S1) to the second surface (S2). The first type semiconductor layered unit 100 includes the first type window layer 110 and the first type ohmic contact layer 120. The first type window layer 110 is disposed between the first type ohmic contact layer 120 and the active layer 200. In the present embodiment, the first type semiconductor layered unit 100 further includes a first type capping layer 130 that is disposed between the first type window layer 110 and the active layer 200. The second type semiconductor layered unit 300 includes the second type capping layer 310, the transition layer 320 and the second type window layer 330, the second type capping layer 310 is disposed between the transition layer 320 and the active layer 200, and the transition layer 320 is disposed between the second type capping layer 310 and the second type window layer 330. The light emitting device further includes a first electrode 140 disposed on the first type ohmic contact layer 120, and a second electrode 340 disposed on the second type window layer 330. Both the first electrode 140 and the second electrode 340 are disposed at a same side of the epitaxial structure.

In certain embodiments, the first type window layer 110 may include the first sub-window layer 111, the second sub-window layer 112 and, optionally, the third sub-window layer 113, disposed in such order along a direction from the second surface (S2) to the first surface (S1), and has n number of a combination of the aforesaid two or three sub-window layers, where n is at least 1. In the embodiment shown in FIG. 7, the first type window layer 110 includes a combination of the first, second and third sub-window layers 111, 112, 113, and n is 1.

In manufacturing of the light-emitting device, the epitaxial structure is first formed on a growth substrate with the first surface (S1) facing the growth substrate, and is then transferred to the substrate 400 with the second surface (S2) bonding to the substrate 400. Subsequently, the growth substrate is removed from the epitaxial structure. The substrate 400 may be a conductive substrate or a non-conductive substrate, or a transparent substrate or a non-transparent substrate. In certain embodiments, the epitaxial structure is bonded to the substrate 400 through a bonding layer 410.

In certain embodiments, as shown in FIG. 7, the light-emitting device further includes an insulating protective layer 500. The insulating protective layer 500 is disposed on an upper surface and a part of a sidewall of the epitaxial structure. In the present embodiment, the insulating protective layer 500 may contain a non-conductive material selected from an inorganic oxide or nitride, for example, silicon dioxide, silicon nitride, titanium oxide, tantalum oxide, niobium oxide, barium titanate, magnesium fluoride, aluminum oxide, or combinations thereof. The insulating protective layer 500 may include a distributed Bragg reflector (DBR) structure formed from alternating layers of two of the aforesaid materials.

As shown in FIG. 7, the second-type window layer 330 may have a roughened surface that is connected to the bonding layer 410 so as to improve the bonding yield.

In addition to the structural features of the light-emitting device described above in the present embodiment, other structural features derived from other light-emitting devices may be added to achieve corresponding purposes.

FIG. 8 is a schematic diagram illustrating an embodiment of a vertical type light-emitting device according to the present disclosure that includes any one of the aforesaid epitaxial structures, a substrate 400 and two electrodes which are disposed respectively at opposing sides of the epitaxial structure. In such structure, almost all current flows vertically through the epitaxial structure of the light-emitting device, which may solve the current spreading distribution problem countered in a planar structure of a light emitting device, enhance the luminous efficiency, and may also address the light-blocking issue caused by the second electrode 340 (i.e., P electrode), thereby increasing light-emission area of the light-emitting device.

Referring to FIG. 8, as previously described, the epitaxial structure has the first surface (S1) and the second surface (S2, and includes the first type semiconductor layered unit 100, the active layer 200, and the second type semiconductor layered unit 300 in such order along the direction from the first surface (S1) to the second surface (S2). The first type semiconductor layered unit 100 includes the first type window layer 110 and the first type ohmic contact layer 120. The first type window layer 110 is disposed between the first type ohmic contact layer 120 and the active layer 200. In the present embodiment, the first type semiconductor layered unit 100 includes a first type capping layer 130 that is disposed between the first type window layer 110 and the active layer 200. The second type semiconductor layered unit 300 includes the second type capping layer 310, the transition layer 320 and the second type window layer 330, the second type capping layer 310 is disposed between the transition layer 320 and the active layer 200, and the transition layer 320 is disposed between the second type capping layer 310 and the second type window layer 330. In other words, the transition layer 320 and the active layer 200 are disposed at the opposing sides of the second type covering layer 310. In manufacturing of the light-emitting device, the epitaxial structure is first formed on a growth substrate with the first surface (S1) facing the growth substrate, and is then transferred to the substrate 400 with the second surface (S2) bonding to the substrate 400 through a bonding layer 410 that is a conductive bonding layer. Subsequently, the growth substrate is removed from the epitaxial structure. A first electrode 140 is formed on the first type ohmic contact layer 120 and a second electrode 340 is formed on a surface of the conductive substrate 400 that is opposite to the second type window layer 330. As a result, the first electrode 140 and the second electrode 340 are disposed at the opposing sides of the epitaxial structure.

In certain embodiments, the substrate 400 is a conductive substrate that may be made of a conductive material such as GaP, SiC, Si or GaAs. The bonding layer 410 may be made of a metal conductive material.

Further, the first type window layer 110 may include the first sub-window layer 111, the second sub-window layer 112 and, optionally, the third sub-window layer 113, disposed in such order along a direction from the second surface (S2) to the first surface (S1), and has n number of a combination of the aforesaid two or three sub-window layers, where n is at least 1. In the embodiment shown in FIG. 8, the first type window layer 110 includes a combination of the first, second and third sub-window layers 111, 112, 113, and n is 1.

In certain embodiments, as shown in FIG. 8, the light-emitting device further includes an insulating protective layer 500. The insulating protective layer 500 is disposed on an upper surface and a part of a sidewall of the epitaxial structure. In the present embodiment, the insulating protective layer 500 may contain a non-conductive material selected from an inorganic oxide or nitride, for example, silicon dioxide, silicon nitride, titanium oxide, tantalum oxide, niobium oxide, barium titanate, magnesium fluoride, aluminum oxide, or combinations thereof.

In addition to the structural features of the light-emitting device described above in the present embodiment, other structural features derived from other light-emitting devices may be added to achieve corresponding purposes.

The present disclosure also provides an embodiment of a light-emitting apparatus. The light-emitting apparatus employs any one of the aforesaid light-emitting devices which may include any one of aforementioned epitaxial structures. The light-emitting apparatus utilizes red or infrared light radiated by the light-emitting device in various applications, e.g., display devices, illumination devices or other optical devices.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
an epitaxial structure having a first surface and a second surface opposite to said first surface, and including
a first type semiconductor layered unit that includes a first type window layer and a first type ohmic contact layer disposed at one side of said first type window layer;
an active layer; and
a second type semiconductor layered unit;
wherein
said first type semiconductor layered unit, said active layer, said second type semiconductor layered unit are disposed in such order along a direction from said first surface to said second surface,
said first type window layer is disposed between said first type ohmic contact layer and said active layer,
said first type ohmic contact layer contains a material represented by Alₓ₁Ga_{y1}InP, where 0≤x1≤1, 0≤y1≤1,
said first type window layer contains a material represented by Alₓ₂Ga_{y2}InP, where 0<x2≤1, 0≤y2≤1, and
said first type ohmic contact layer has an Al content lower than an Al content of said first type window layer.

2. The light-emitting device according to claim 1, wherein in the Alₓ₁Ga_{y1}InP and Alₓ₂Ga_{y2}InP, X₂−X₁≥0.2.

3. The light-emitting device according to claim 1, wherein in the Alₓ₁Ga_{y1}InP and Alₓ₂Ga_{y2}InP, X₂ ranges from 0.2 to 1 and X₁ ranges from 0 to 0.8.

4. The light-emitting device according to claim 1, wherein in the Alₓ₁Ga_{y1}InP and Alₓ₂Ga_{y2}InP, X₂ ranges from 0.5 to 1 and X₁ ranges from 0.2 to 0.5.

5. The light-emitting device according to claim 1, wherein said first type ohmic contact layer has a thickness larger than 300 Å and smaller than a thickness of said first type window layer.

6. The light-emitting device according to claim 1, wherein said first type window layer has a thickness smaller than 5 μm.

7. The light-emitting device according to claim 1, wherein said first type ohmic contact layer is N-type doped and said first type window layer is N-type doped, a doping concentration of said first type window layer being lower than a doping concentration of said first type ohmic contact layer.

8. The light-emitting device according to claim 7, wherein the doping concentration of said first type ohmic contact layer is higher than 4E+18/cm³ and the doping concentration of said first type window layer ranges from 4E+17/cm³ to 4E+18/cm³.

9. The light-emitting device according to claim 1, wherein said first type window layer includes a first sub-window layer and a second sub-window layer disposed in such order along the direction.

10. The light-emitting device according to claim 9, wherein said first sub-window layer contains aluminum indium phosphide, and said second sub-window layer contains aluminum gallium indium phosphide.

11. The light-emitting device according to claim 1, wherein said first type window layer includes a first sub-window layer, a second sub-window layer and a third sub-window layer disposed in such order along the direction.

12. The light-emitting device according to claim 11, wherein said first sub-window layer contains a material represented by AlₐGa_{b}InP, said second sub-window layer contains a material represented by Al_{c}Ga_{d}InP and said third sub-window layer contains a material represented by AlₑGaᵣInP, where a>e>c, d≥0, f≥0.

13. The light-emitting device according to claim 11, wherein said first sub-window layer has a thickness of TH1, said second sub-window layer has a thickness of TH2, and said third sub-window layer has a thickness of TH3, where 0<TH2<1000 Å<TH3<TH1.

14. The light-emitting device according to claim 11, wherein each of said first sub-window layer, said second sub-window layer and said third sub-window layer is n-type doped, a doping concentration of said first sub-window layer is H₁, a doping concentration of said second sub-window layer is H₂, and a doping concentration of said third sub-window layer is H₃, where 0<H₂<H₃<H₁<4E+18/cm³.

15. The light-emitting device according to claim 9, wherein a number of a combination of said first sub-window layer and said second sub-window layer is at least 1.

16. The light-emitting device according to claim 11, wherein a number of a combination of said first sub-window layer, said second sub-window layer and said third sub-window layer is at least 1.

17. The light-emitting device according to claim 1, wherein said second type semiconductor layered unit includes a second type capping layer, a transition layer and a second type window layer, said second type capping layer is disposed between said transition layer and said active layer, and said transition layer is disposed between said second type capping layer and said second type window layer.

18. The light-emitting device according to claim 1, wherein said epitaxial structure radiates red light.

19. The light-emitting device according to claim 1, wherein said light-emitting device is a vertical type light-emitting device or a flip chip light-emitting device.

20. A light-emitting apparatus, comprising a light-emitting device according to claim 1.
